(19) United States
(12) Patent Application Publication
(10) Pub. No.: US 2016/0267996 A1
(43) Pub. Date: Sep. 15, 2016

(54) MEMORY SYSTEM

(71) Applicant: KABUSHIKI KAISHA TOSHIBA, Tokyo (JP)

(72) Inventors: Sanad BUSHNAQ, Yokohama Kanagawa (JP); Masanobu SHIRAKAWA, Chigasaki Kanagawa (JP)

(21) Appl. No.: 14/995,045

(22) Filed: Jan. 13, 2016

(30) Foreign Application Priority Data
Mar. 13, 2015 (JP) 2015-051408

(51) Int. Cl. G11C 16/16

(52) U.S. Cl. CPC G11C 16/16

(57) ABSTRACT

A memory system includes a semiconductor memory device that includes a plurality of memory cells, and a controller that controls an operation of the semiconductor memory device to set the memory cells to have a threshold voltage distribution corresponding to data being written therein, when data is being written in the memory cells, and to set the memory cells to have a neutral threshold voltage distribution, the neutral threshold voltage distribution being different from any of a plurality of threshold voltage distributions corresponding to valid data, when data is not being written in the memory cells.

### CROSS-REFERENCE TO RELATED APPLICATION

This application is based upon and claims the benefit of priority from Japanese Patent Application No. 2015-051408, filed Mar. 13, 2015, the entire contents of which are incorporated herein by reference.

### FIELD

Embodiments described herein relate generally to a memory system.

### BACKGROUND

A NAND type flash memory in which memory cells are arranged in a three-dimensional manner is known.

### DESCRIPTION OF THE DRAWINGS

FIG. 1 is a diagram illustrating a memory system according to an embodiment.

FIG. 2 is a diagram illustrating a configuration example of a semiconductor memory.

FIG. 3 is a diagram illustrating an example of an internal configuration of a memory cell array.

FIG. 4 is a diagram illustrating an example of an internal configuration of the memory cell array.

FIGS. 5A to 5C are schematic diagrams for explaining a memory system according to a first embodiment.

FIG. 6 is a flowchart illustrating an operation example of the memory system according to the first embodiment.

FIG. 7 is a timing diagram illustrating an operation example of the memory system according to the first embodiment.

FIGS. 8A and 8B are schematic diagrams for explaining an operation example of the memory system according to the first embodiment.

FIG. 9 is a flowchart illustrating an operation example of the memory system according to the first embodiment.

FIG. 10 is a flowchart illustrating an operation example of the memory system according to the first embodiment.

FIG. 11 is a timing diagram illustrating an operation example of the memory system according to the first embodiment.

FIG. 12 is a timing diagram illustrating an operation example of the memory system according to the first embodiment.

FIG. 13 is a flowchart illustrating a semiconductor memory according to a second embodiment.

### DETAILED DESCRIPTION

Embodiments now will be described more fully hereinafter with reference to the accompanying drawings. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, such elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, when the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, when the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross section and perspective illustrations that are schematic illustrations of the embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A memory system which minimizes deterioration in retention characteristics of a memory cell is provided.

In general, according to one embodiment, a memory system includes a semiconductor memory device that includes a plurality of memory cells, and a controller that controls an operation of the semiconductor memory device to set the memory cells to have a threshold voltage distribution corresponding to data being written therein, when data is being written in the memory cells, and to set the memory cells to have a neutral threshold voltage distribution, the neutral threshold voltage distribution being different from any of a plurality of threshold voltage distributions corresponding to valid data, when data is not being written in the memory cells.

Hereinafter, with reference to the drawings, the present embodiment will be described in detail. In the following description, structural elements having the same function and configuration are given the same reference numerals, and repeated description will be omitted.

### (1) First Embodiment

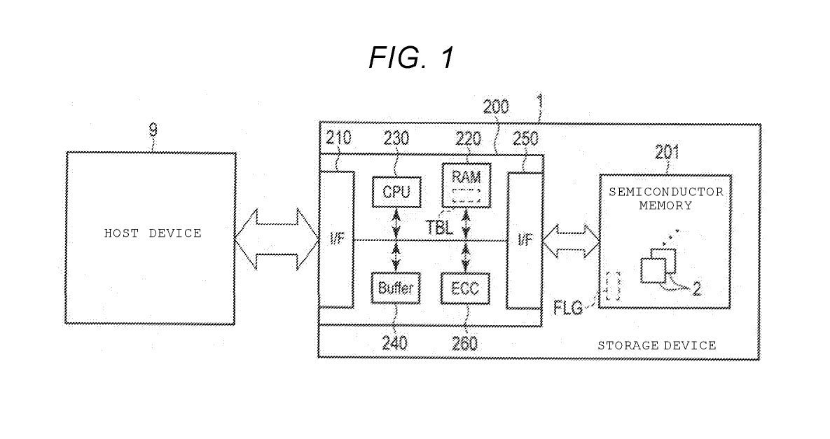

With reference to FIGS. 1 to 12, a memory system according to a first embodiment will be described.

### a) Entire Configuration

With reference to FIGS. 1 to 5, the memory system according to the first embodiment will be described. As illustrated in FIG. 1, the memory system includes a storage device 1 and a host device 9.

The host device 9 requests the storage device 1 to perform writing or erasing of data or reading of data.

The storage device 1 is coupled to the host device 9 via an interface 210. The storage device 1 and the host device 9 transmit data based on a standard set in the interface 210 via, for example, a connector, wireless communication, or the Internet.

The storage device 1 includes a memory controller 200.

The memory controller 200 includes a host interface circuit (interface) 210, an internal memory (RAM) 220, a processor (CPU) 230, a buffer memory 240, a NAND interface circuit 250, and an ECC circuit 260.

The host interface circuit 210 is coupled to the host device 9 via a controller bus. The host interface circuit 210 controls communication with the host device 9. The host interface circuit 210 transmits a request and data from the host device 9 to the CPU 230 and the buffer memory 240. The host interface circuit 210 transmits data in the buffer memory 240 to the host device 9 in response to a command from the CPU 230.

The memory interface circuit 250 is connected to the semiconductor memory 201 via a bus and controls communication for the semiconductor memory 201. The memory interface circuit 250 transmits a command from the CPU 230 to the semiconductor memory 201. The memory interface circuit 250 transmits an address and data from the buffer memory 240 to the semiconductor memory 201 along with a command when data is written to the semiconductor memory 201. When data is read from the semiconductor memory 201, the memory interface circuit 250 transmits an address to the semiconductor memory 201 along with a command. The memory interface circuit 250 receives data read from the semiconductor memory 201 and transmits the data to the buffer memory 240.

The CPU 230 controls the entire operation of the controller 200. For example, when a write request is received from the host device 9, the CPU 230 issues a write command based on the interface in response to the request. In the same manner as during writing, during reading and erasing, the CPU 230 issues a command corresponding to the request from the host device 9. The CPU 230 performs various processes for managing the semiconductor memory 201 such as wear leveling. The CPU 230 performs various calculations such as data encryption or randomizing.

The ECC circuit 260 performs error checking and correcting (ECC) processes on data. The ECC circuit 260 generates a parity based on data to be written during writing of the data. During reading of data, the ECC circuit 260 generates syndrome from the parity so as to detect an error, and corrects the detected error. The CPU 230 may also have the function of the ECC circuit 260.

The internal memory 220 is a semiconductor memory such as a DRAM, and is used as a work memory (work area) of the CPU 230. The internal memory 220 holds firmware for managing the semiconductor memory 201, various management tables TBL, and the like. The CPU 230 refers to information in the management tables TBL and controls an operation of the semiconductor memory 201.

The semiconductor memory 201 is a memory device which includes one or more memory chips 2 in a package. The semiconductor memory 201 is, for example, a NAND type flash memory. The storage device 1 (or the memory system) including a flash memory is, for example, a memory card (for example, an SD™ card), a USB memory, or a solid state drive (SSD).

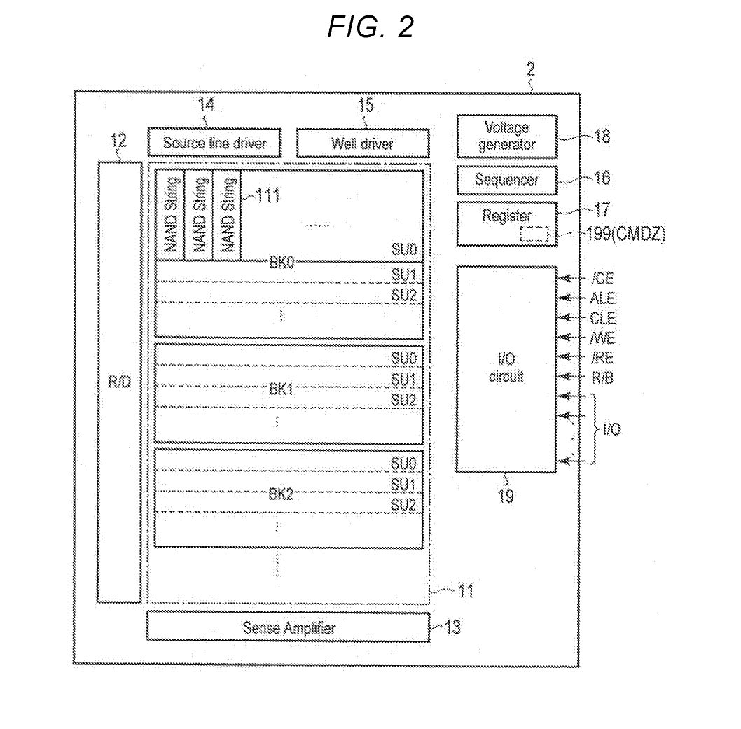

Referring to FIG. 2, each of the memory chips 2 of the flash memory 201 includes a memory cell array 11, and a plurality of circuits (hereinafter, referred to as peripheral circuits) controlling an operation of the memory cell array 11.

For example, the NAND type flash memory 201 includes the memory cell array 11, a row decoder 12, a sense amplifier 13, a source line driver 14, a well driver 15, a sequencer 16, a register 17, a voltage generator 18, and an input and output circuit 19.

The memory cell array 11 includes a plurality of blocks BK (BK0, BK1, BK2, . . . ). A block BK represents the erasure unit of data, and data items in the block BK are collectively erased. Each of the blocks BK includes a plurality of string units SU (SU0, SU1, SU2, . . . ). Each of string units SU includes an aggregate of NAND strings 111. Each of the NAND strings 111 includes a plurality of memory cells which are connected in series to each other. The number of blocks in the memory cell array 11, the number of string units in a single block BK, the number of NAND strings in a single string unit SU, or the number of memory cells in a single NAND string is arbitrary.

The row decoder 12 decodes a block address or a page address, and selects one word line of a block corresponding to the address. The row decoder 12 applies voltages for operating the flash memory 201 to selected word lines and unselected word lines.

The sense amplifier 13 senses and amplifies a signal which is output from the memory cell to a bit line during reading of data. The sensed and amplified signal is treated as data stored in the memory cell. The sense amplifier 13 transmits data to be written (hereinafter, referred to as data to be written) to the memory cell during writing of data.

The source line driver 14 applies a voltage to a source line.

The well driver 15 applies a voltage to a well region where the NAND string 111 is provided.

The register 17 holds various signals. The register 17 holds, for example, a status of a data writing operation or a data erasing operation. Consequently, the flash memory may notify the controller 200 whether or not an operation has been normally completed. The register 17 holds a command, an address, and the like received from the controller 200. The register 17 may hold various tables. The register 17 includes a command register 199 which may hold various commands CMDZ which are applied to the memory system of the present embodiment.

The input and output circuit 19 is an interface for signals which are transmitted and received between the controller 200 and the flash memory 201.

The sequencer 16 controls the entire operation of the flash memory 201 (the memory chips 2). The sequencer 16 controls an internal operation of the flash memory 201 based on the signal which is transmitted and received between the controller 200 and the flash memory 201.

The controller 200 and the flash memory 201 transmit and receive a chip enable signal /CE, an address latch enable signal ALE, a command latch enable signal CLE, a write enable signal /WE, a read enable signal /RE, an input/output signal I/O, and a ready/busy signal R/B.

The chip enable signal /CE enables the flash memory 201. The address latch enable signal ALE notifies the flash memory 201 that an input signal I/O on an I/O line is an address signal. The command latch enable signal CLE notifies the flash memory 201 that an input/output signal I/O is a command. The write enable signal /WE is a signal for inputting an input/output signal I/O into the flash memory 201. The read enable signal /RE is a signal for outputting an input/output signal I/O to the controller 200. The ready/busy signal R/B notifies the controller 200 whether the flash memory 201 is in a ready state (a state in which a signal may be received) or a busy state (a state in which a signal cannot be received).

For example, during access to the flash memory 201 (for example, data writing), the controller 200 issues a command (for example, the command 80H) via the I/O line and also sets the command latch enable signal CLE to be in an active state (for example, an “H” level). The controller 200 outputs a column address to the I/O line for two cycles and also sets the address latch enable signal ALE to be in an active state (for example, an “H” level). The controller 200 outputs a page address to the I/O line for three cycles. These commands and addresses are stored in, for example, the register 17 of the flash memory 201.

Then, data is transmitted between the controller 200 and the flash memory 201 for a plurality of cycles via the I/O line. During this period of time, the address latch enable signal ALE and the command latch enable signal CLE are set to be inactive (for example, an “L” level). The controller 200 issues a command (for example, the command “10H”) indicating ending of the transmission of the data and also sets the command latch enable signal CLE to be in an active state (for example, an “L” level).

During writing of data, the controller 200 sets the write enable signal /WE to be in an active state (for example, an “H” level) when issuing a command, an address, data, and the like. Consequently, a signal is received by the flash memory 201 when the write enable signal /WE is toggled.

An operation for the memory cell array 11 is performed based on the control signals.

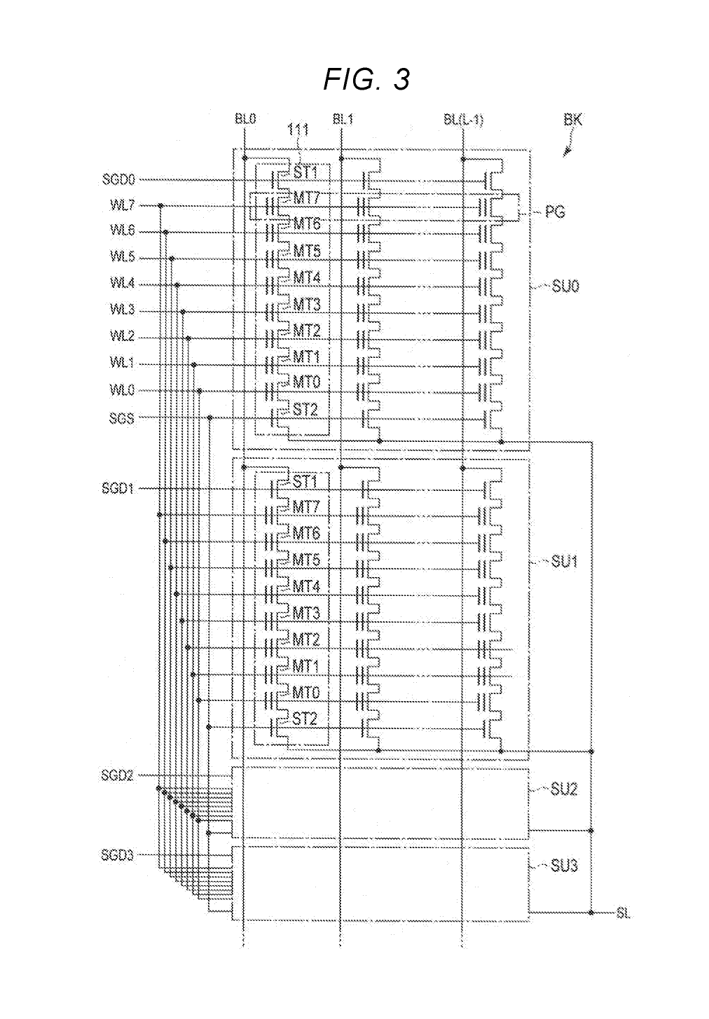

FIG. 3 is a schematic diagram illustrating an example of an internal configuration of the memory cell array.

As illustrated in FIG. 3, the block BK includes, for example, four string units SU (SU0 to SU3). Each of the string units SU includes the plurality of NAND strings 111.

Each of the NAND strings 111 includes a plurality of (for example, eight) memory cells MT (MT0 to MT7) and select transistors ST1 and ST2. Each of the memory cells (memory cell transistors) MT includes a stacked gate which includes a control gate and a charge storage layer. The memory cells MT retain data in a substantially nonvolatile manner. The number of memory cells in the NAND string 111 is not limited to eight. The memory cells MT are connected in series to the select transistors ST1 and ST2. One end of the memory cell MT7 is connected to one end of the select transistor ST1. One end of the memory cell MT0 is connected to one end of the select transistor ST2.

A plurality of select gate lines SGD0 to SGD3 are respectively connected to gates of the select transistors ST1 of the string units SU0 to SU3.

A single select gate line SGS is connected in common to gates of the select transistors ST2 in the plurality of string units SU.

Word lines WL0 to WL7 are connected in common to control gates of the memory cells located at the same height with respect to a semiconductor substrate in the memory cells MT0 to MT7 of the same block BK.

The word lines WL0 to WL7 and the select gate line SGS are connected in common to the plurality of string units SU0 to SU3 of the same block BK. In contrast, the select gate lines SGD are separately provided for the respective string units SU0 to SU3 even in the same block BK.

In the memory cell array 11, among the NAND strings 111 which are arranged in a matrix, the other ends of the select transistors ST1 of the NAND strings 111 of the same column are connected in common to one of a plurality of bit lines BL (BL0 to BL(L−1)). The bit lines BL are connected in common to the NAND strings 111 across the plurality of blocks BK. Here, (L−1) is a natural number of 1 or more.

In the memory cell array 11, drains of the select transistors ST1 of the NAND strings 111 of the same column are connected in common to the bit lines BL. In other words, the bit lines BL are connected in common to the NAND strings 111 in the plurality of string units SU0 to SU3.

The other end of the select transistor ST2 is connected to a source line SL.

Data items of the memory cells MT in the same block BK are collectively erased. Reading and writing of data are collectively performed for the plurality of memory cells MT which are connected in common to any one of the word line WL in any one of the string units SU of any one of the blocks BK. The unit of reading and writing of data is referred to as a “page”.

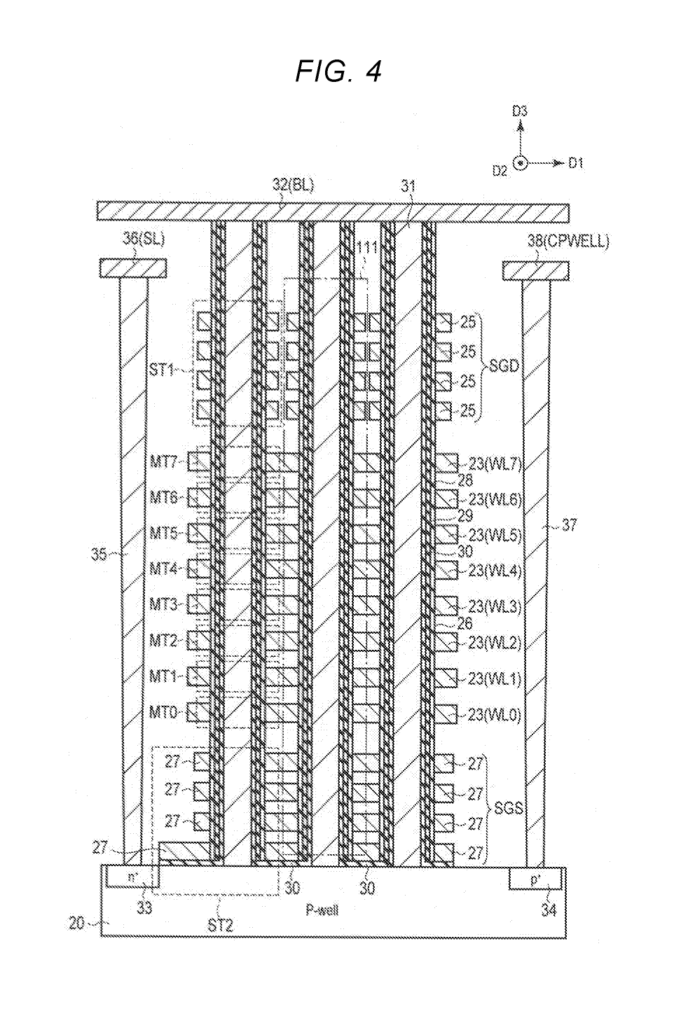

FIG. 4 illustrates a sectional structure of the memory cell array 11, and three string units are extracted and illustrated for simplification.

A plurality of NAND strings 111 are provided on a p-type well region 20 inside a semiconductor region (for example, a Si substrate).

Semiconductor pillars 31 are provided on the p-type well region 20. The semiconductor pillar 31 extends in a direction perpendicular to a surface of the well region 20 (substrate). The semiconductor pillars 31 function as current paths of the NAND strings 111. The semiconductor pillars 31 are regions where a channel of each transistor is formed during operations of the memory cells MT, and the select transistors ST1 and ST2.

A gate insulating film 30, a charge storage layer 29 (insulating film), and a block insulating film 28 are sequentially provided on a side surface of the semiconductor pillar 31 from the semiconductor pillar 31 side. Hereinafter, the layered films including the gate insulating film 30, the charge storage layer 29, and the block insulating film 28 are referred to as memory films.

A plurality of conductive layers 23, 25 and 27 are stacked on the well region 20 via interlayer insulating films (not illustrated). Each of the conductive layers 23, 25 and 27 is provided on the side surface of the semiconductor pillar 31 via the memory films.

The plurality of conductive layers 23 respectively function as the word line WL.

The plurality of (in this example, four) conductive layers 25 are connected to the same drain side select gate line SGD in each of the NAND strings 111. The four conductive layers 25 each function as a gate electrode of a single select transistor ST1.

The plurality of (in this example, four) conductive layers 27 are connected to the same source side select gate line SGS. The four conductive layers 27 each function as a gate electrode of a single select transistor ST2. For example, the conductive layers (select gate line) 27 in the same string unit SU are connected to each other.

A conductive layer 32 which functions as the bit line BL is provided on an upper end of the semiconductor pillars 31. The bit line BL is connected to the sense amplifier 13.

An n⁺-type impurity diffusion layer 33 and a p⁺-type impurity diffusion layer 34 are provided in the surface region of the well region 20.

A contact plug 35 is provided on the diffusion layer 33. A conductive layer 36 is provided on the contact plug 35. The conductive layer 36 functions as the source line SL. The source line SL is connected to the source line driver 14. A gate insulating film 30 is formed on the well region 20 between the NAND strings 111 adjacent to each other. The conductive layers 27 and the gate insulating film 30 extend to the vicinity of the diffusion layer 33. Consequently, when the select transistor ST2 is turned on, the channel of the select transistor ST2 electrically connects the memory cell transistor MT0 to the diffusion layer 33.

A contact plug 37 is provided on the diffusion layer 34. A conductive layer 38 is provided on the contact plug 37. The conductive layer 38 functions as a well wiring CPWELL. The well wiring CPWELL is connected to the well driver 15. When a voltage is applied to the well wiring CPWELL, a voltage may be in turn applied to the semiconductor pillar 31.

As mentioned above, in each of the NAND strings 111, the select transistor ST2, the plurality of memory cells MT, and the select transistor ST1 are sequentially stacked on the well region 20.

The plurality of NAND strings 111 are arranged in a depth direction of FIG. 4. Each of the string units SU is an aggregate of a plurality of NAND strings 111 which are arranged in the depth direction.

In the present embodiment, a structure, an operation, and a manufacturing method of the memory cell array having the three-dimensional structure employ the configurations disclosed in, for example, U.S. patent application Ser. No. 12/407,403, filed on Mar. 19, 2009, entitled “Three-dimensional stacked nonvolatile semiconductor memory”, U.S. patent application Ser. No. 12/406,524, filed on Mar. 18, 2009, entitled “Three-dimensional stacked nonvolatile semiconductor memory”, U.S. patent application Ser. No. 12/679,991, filed on Mar. 25, 2010, entitled “Nonvolatile semiconductor memory device and manufacturing method thereof”, and U.S. patent application Ser. No. 12/532,030, filed on Mar. 23, 2009, entitled “Semiconductor memory and manufacturing method thereof”. The entire contents of these application are incorporated by reference herein.

In the present embodiment, the memory cell array 11 may have a two-dimensional structure. In the memory cell array having the two-dimensional structure, the memory cell MT includes a gate insulating film on a semiconductor substrate (well region), a charge storage layer (for example, a floating gate electrode including a silicon film) on the gate insulating film, a block insulating film (inter-gate insulating film) on the charge storage layer, and a control gate electrode on the block insulating film.

The flash memory stores data by associating a threshold voltage of the memory cell MT with the data.

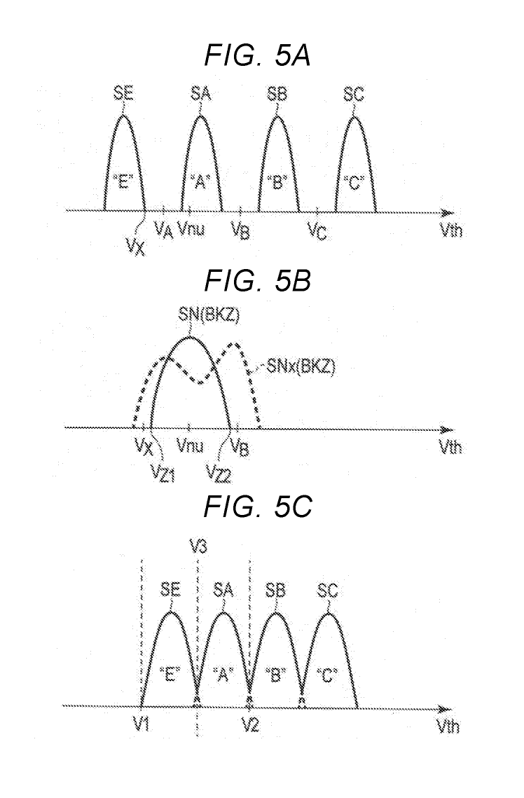

FIG. 5 is a schematic diagram illustrating a correspondence relationship between a threshold value distribution (a threshold value state) of the memory cell and data. A threshold voltage of the memory cell MT belongs to any one of four different threshold value states (an erased state SE, and program states SA, SB and SC)

When a threshold voltage of the memory cell MT belongs to any one of the program states (A, B and C states) SA, SB and SC, electrons in an amount (number) corresponding to data to be stored are injected into the charge storage layer 29.

When a threshold voltage of the memory cell MT belongs to the erased state SE, holes are injected into the charge storage layer 29 (or electrons are ejected out of the charge storage layer 29).

In order to determine a threshold voltage (data in the memory cell) of the memory cell, determination levels (reading levels) V_{A}, V_{B} and V_{C} of the threshold value distributions are applied to the gate (word line) of the memory cell MT.

When the memory cell MT is set to be in the erased state and one of the program states, the block BK of the flash memory 201 may have the following states.

In the flash memory 201, the memory cell array 11 includes a block which cannot be used as a data memory region and a block which may be used as a data memory region.

The block which cannot be used is classified into a block (a congenital defective block) which cannot be used when the flash memory is shipped, and a block (an acquired defective block) which cannot be used due to deterioration caused by use of the flash memory. Hereinafter, a block which cannot be used is referred to as a defective block (or an unusable block).

Blocks excluding the defective blocks are used to store data. Hereinafter, a block which is used to store data is referred to as a usable block.

The usable block stores data (hereinafter, referred to as valid data) which is used in the host device 9 and the controller 200. Hereinafter, a block which stores effective data in at least a portion (for example, a page) of the block is referred to as a valid data block.

Data in a valid data block is updated in the block unit or the page unit according to an operation situation of the memory system (storage device).

As a result of the update, data of all pages in a block may be invalid (a state in which the data is not used in the host device 9 and the controller 200). Such a block of which data of all pages becomes invalid may be generated due to, for example, garbage collection or compaction, or fragmentation of data. Hereinafter, a block of which data of all pages becomes invalid (a block which stores only invalid data) is referred to as an invalid data block (or an unnecessary block). Each memory cell MT in an invalid data block has a threshold voltage associated with data before becoming invalid.

Depending on an operation situation of the memory system, threshold values of all memory cells MT in the block BK may belong to an erased state (E state) due to an erasure operation. Hereinafter, a block in which threshold values of all the memory cells are in an erased state is referred to as an erased block.

The present embodiment is described with using an example in which data is erased in the block unit, but is not limited thereto, and data may be erased in the unit which is smaller than the block. Such an erasure method is disclosed in, for example, U.S. patent application Ser. No. 13/235,389, filed on Sep. 18, 2011, entitled “Nonvolatile semiconductor memory device”, and U.S. patent application Ser. No. 12/694,690, filed on Jan. 27, 2010, entitled “Non-volatile semiconductor storage device”. The entire contents of these applications are incorporated by reference herein.

In the memory cell in a program state (a state in which an electron is stored in a memory film), there is a possibility that the gate insulating film 30 may deteriorate due to a potential difference between the semiconductor region (semiconductor pillar) 31 and the charge storage layer 29.

When a threshold value of the memory cell is in an erased state, there is a possibility that an electron may be captured in neutral defects of the gate insulating film. When the electron captured in the gate insulating film is released after the threshold value of the memory cell transitions from the erased state to a program state, a potential of the charge storage layer of the memory cell changes. For this reason, when the threshold value of the memory cell belongs to the program state, there is a possibility that a potential may unintentionally change. As a result, after data is written, data to be stored in the memory cell may not be retained, and thus a retention characteristic of the memory cell may be deteriorated.

The memory system according to the present embodiment sets a threshold value of the memory cell MT of a block which does not retain valid data to be in an electrically neutral state.

Hereinafter, a state (electrically neutral state) in which the charge storage layer (memory film) of the memory cell is unlikely to be positively or negatively charged, and a state in which a charging level of the charge storage layer is low are referred to as a neutral state. A certain threshold voltage (for example, a threshold voltage of the memory cell including the charge storage layer which is unlikely to be positively or negatively charged) of the memory cell in a neutral state is referred to as a neutral threshold voltage Vnu.

A neutral threshold voltage Vnu of the memory cell MT changes depending on a material of the memory cell MT. For example, a neutral threshold voltage of the memory cell obtained when a material of the charge storage layer is p-type silicon is higher than a neutral threshold voltage of the memory cell obtained when a material of the charge storage layer is n-type silicon. A neutral threshold voltage of the memory cell obtained when a material of the charge storage layer is silicon nitride is higher than a neutral threshold voltage of the memory cell obtained when a material of the charge storage layer is p-type silicon.

For example, the memory cell MT tends to have values around 0 V as a neutral threshold voltage Vnu.

The memory cell MT is electrically most stable in a state in which the charge storage layer (memory film) is neither positively nor negatively charged (an electrically neutral state). When the charge storage layer is in an electrically neutral state, a potential difference applied to the gate insulating film is reduced compared with a case where the charge storage layer is strongly positively charged (for example, the memory cell is in a threshold value state which is equal to or greater than the B state). When the charge storage layer is in an electrically neutral state, capturing of an electron in the gate insulating film is reduced compared with a case where the charge storage layer is positively charged (a case where the memory cell is in an erased state).

In the present embodiment, when a certain block in the memory cell array 11 is a block (invalid data block) which stores valid data or is an erased block, the memory controller 200 (memory system) sets a threshold voltage of the memory cell MT in the valid data block or the erased block to be in a state corresponding to the vicinity of the neutral threshold voltage Vnu of the memory cell MT as illustrated in FIG. 5B.

Consequently, the memory controller 200 sets a state (mode) of a block which does not retain valid data to be in a first mode in which the memory cells of the block may be conserved so their data retention characteristic is not deteriorated. The memory controller 200 causes the block which does not retain valid data to wait in the first mode until the block is selected as a data writing target.

Hereinafter, a block (a block including memory cells in a neutral state) set to be in the first mode is referred to as a conservation mode block BKZ.

For example, the memory controller 200 sets a threshold voltage of memory cells in a block to be set to be in the conservation mode block BKZ, to be in a state SN included in a certain range from V_{Z1} to V_{Z2} (V_{X} to V_{B}).

For example, the lower limit value V_{Z1} of a threshold voltage corresponding to a neutral state of the memory cell MT is higher than the upper limit value V_{X} of a threshold value corresponding to an erased state. For example, the upper limit value V_{Z2} of a threshold voltage corresponding to a neutral state of the memory cell MT is lower than the upper limit value of a threshold value corresponding to the lowest program state (herein, the A state).

For example, a range (a range in which a memory cell is allowed to be in an electrically neutral state) of a threshold value distribution of the memory cell in the conservation mode block is −0.3 V to +2.0 V.

However, a neutral threshold voltage of the memory cell MT differs depending on a material of the memory cell MT. For this reason, as long as the memory cell MT may be maintained in an electrically neutral state in the conservation mode block BKZ, a range (a range of a voltage value with a certain neutral threshold voltage Vnu as a reference) of a voltage value corresponding to the neutral state is not limited to the above-described values.

In the memory system according to the present embodiment, the charge storage layer of the memory cell in a block which does not retain valid data is preferably prevented from being strongly positively or negatively charged. Thus, a threshold value distribution of the memory cell in the conservation mode block BKZ may be a disordered distribution as indicated by SNx in FIG. 5B.

Even when two threshold value states (threshold value distributions) are not completely separated from each other, the two threshold value states may be differentiated from each other so that one is a first threshold value state and the other is a second threshold value state with a certain voltage within a range of the two threshold value states as a boundary.

For example, as illustrated in FIG. 5C, regarding two threshold value states SE and SA which are separated from each other within a range from a first voltage value to a second voltage value, with a third voltage value V3 (a voltage value at an intersection between the two the threshold value distributions) between a first voltage value V1 and a second voltage value V2 as a boundary, a range from the first voltage value V1 to below the third voltage value V3 is referred to as a first threshold value state SE, and a range from the third voltage value V3 to below the second voltage value V2 is referred to as a second threshold value state SA. The first threshold value state and the second threshold value state which are separated from each other (the consecutive first and second states) may have peaks at different voltages.

For example, the memory controller 200 may detect whether or not the block BK is in the conservation mode based on the management table TBL of the memory controller 200 or a flag FLG of the flash memory 201.

As mentioned above, in the memory system (storage device) according to the present embodiment, the controller 200 and the flash memory 201 have a function of converting an invalid data block and an erased block into a conservation mode block.

Consequently, the flash memory 201 of the memory system according to the present embodiment may prevent deterioration in the retention characteristic of the memory cell MT.

### (b) Operation Examples

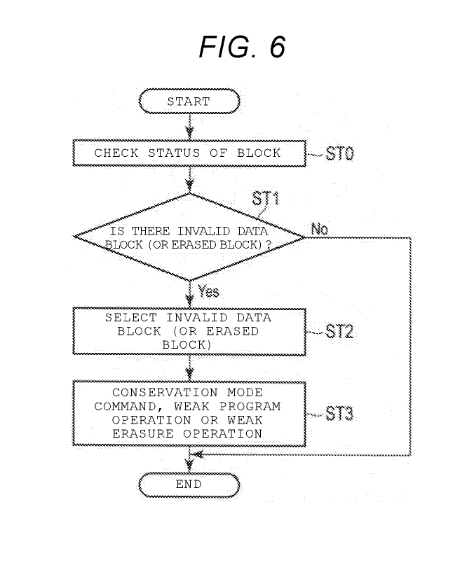

With reference to FIGS. 6 to 12, operation examples of the memory system (the storage device and the semiconductor memory) according to the present embodiment will be described.

Herein, operation examples of the memory system according to the present embodiment will be described with reference not only to FIGS. 6 to 11 but also to FIGS. 1 to 5.

Hereinafter, for differentiation of description, a program operation performed when a block is set to be in a conservation mode is referred to as a weak program operation, and an erasure operation performed when a block is set to be in a conservation mode is referred to as a weak erasure operation.

<Setting of Conservation Mode Block>

As in the following example, the memory controller 200 (or the host device 9) sets a block in the memory cell array 11 of the flash memory 201 as a conservation mode block. For example, a sequence of setting a conservation mode is executed in a certain cycle (for example, a standby state) in which the flash memory 201 is used, or when there is a request from the host device 9 (during a test step, during compaction, or during garbage collection).

FIG. 6 is a flowchart illustrating an operation example (a control method for the memory system or the flash memory) of the memory system. In the memory system (storage device), during a sequence for setting the block BK to be in the conservation mode, the memory controller 200 checks statuses (a valid state, an invalid state, and an erased state) of the block BK of the flash memory 201 by referring the various management tables TBL of the memory space (memory cell array) of the flash memory 201 (step ST0).

In the flash memory 201 during use of the memory system, a usable block in the memory cell array 11 may include at least one of a valid data block, an erased block, and an invalid data block depending on data provided from an external device and an operation situation of the memory system.

The memory controller 200 determines a data retention state of a block which is selected as a determination target based on a status of each block BK in the management table TBL, and detects a block (for example, a block storing only invalid data) in which retention of data is not necessary (step ST1). In step ST1, an erased block may be detected.

When the determined block is an invalid data block or an erased block, the memory controller 200 starts an operation for setting the valid data block or the erased block to be in the conservation mode.

In relation to the valid data block (or the erased block) to be set to be in the conservation mode, the memory controller 200 transmits a command for setting the block to be in the conservation mode to the flash memory (step ST2). Thus, the memory controller instructs the flash memory 201 to perform various operations for setting the valid data block to be in the conservation mode. The memory controller 200 controls levels of control signals such as various enable signals. The memory controller 200 outputs a command and an address to the I/O line as input/output signals I/O at a timing which is synchronized with transition of a level of the control signal.

The flash memory 201 performs a weak program operation on a block (a block to be set to be in the conservation mode) indicated by the address from the memory controller 200 based on an instruction (a command indicating the weak program operation and a control signal) from the memory controller 200.

The flash memory 201 collectively performs the weak program or weak erasure operation on all pages (memory cells), for example, in the erased block or the invalid data block based on a conservation mode command CMDZ.

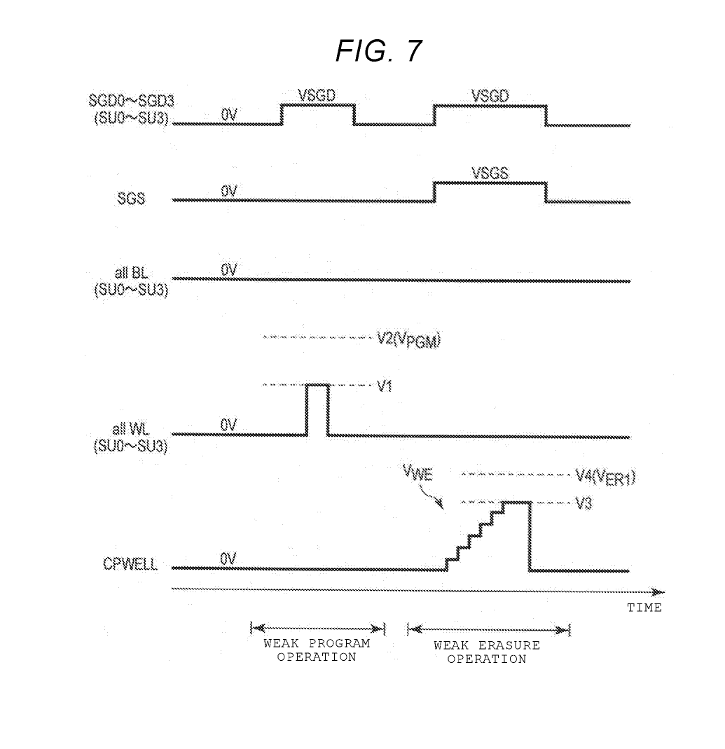

FIG. 7 is a timing diagram illustrating changes in potentials of respective lines of the flash memory. In the weak program operation, the flash memory 201 controls the bit line BL, the source line SL, and a potential CPWELL of the well region 20. The flash memory 201 applies a voltage of 0 V to all the bit lines BL in the valid data block (all the string units SU).

After voltages VSGD and VSGS are respectively applied to the select gate lines SGD and SGS, the flash memory 201 applies a program voltage (hereinafter, referred to as a weak program voltage) V_{WP} for performing the weak program operation to all the word lines WL in the invalid data block as illustrated in FIG. 7.

A voltage value V1 of the weak program voltage V_{WP} is, for example, equal to or smaller than the minimum voltage value (initial value) V2 of a program voltage V_{PGM} for writing valid data.

For example, when the memory cell array 11 has the configuration illustrated in FIGS. 3 and 4, the flash memory 201 applies the voltage VSGD to all the drain side select gate lines SGD0 to SGD3 in relation to all the string units SU in the block to be set to be in the conservation mode as illustrated in FIG. 7. Thus, during the weak program operation, the select transistor ST1 of each of the string units SU is turned on, and thus all the string units SU in the block BK are selected (activated).

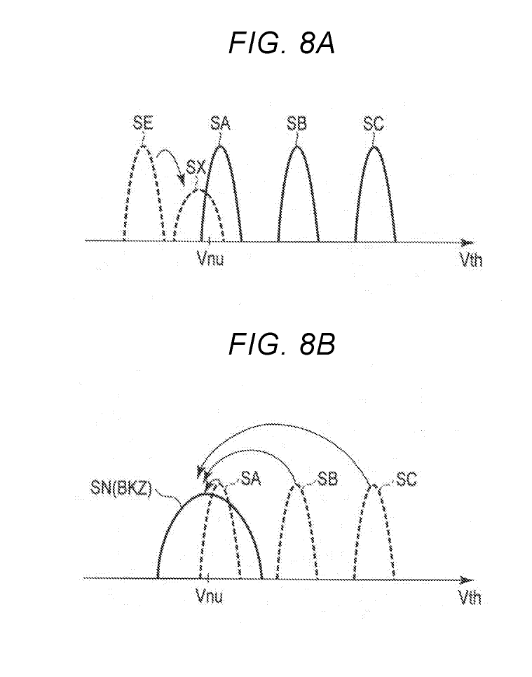

Consequently, as shown in FIG. 8A which illustrates a change in a threshold voltage of the memory cell during the weak program operation, among the memory cells in the erased block, a threshold voltage of the memory cell MT having a threshold voltage which is lower than the neutral threshold voltage Vnu shifts to a state SX having a value (for example, about 0 V) around the neutral threshold voltage Vnu so as to shift to a threshold voltage which is higher than a threshold value Vx in the erased state.

The application of the weak program voltage V_{WP} may be performed twice or more in a consecutive or non-consecutive manner in one conservation mode setting sequence. When the application of the weak program voltage V_{WP} is performed multiple times, a voltage value of the weak program voltage V_{WP} may differ for each timing of the application of the weak program voltage V.

In the weak program operation, verification after the weak program voltage V_{WP} is applied may not be performed. The weak program operation is different from a program operation for valid data (data to be stored) in terms of the presence or absence of data to be written, the presence or absence of verification, the number of string units which are selected (activated) when a program voltage is applied, the number of selected word lines, and the magnitude of the program voltage.

After the weak program operation is performed, the memory controller 200 controls a control signal and input and output signals so as to instruct the flash memory 201 to perform a weak erasure operation on the invalid data block.

The flash memory 201 performs the weak erasure operation on the selected block based on the conservation mode command and various control signals.

In the weak erasure operation under the control of the memory controller 200, the flash memory 201 controls potentials of the select gate lines SGD and SGS and the source line SL.

As illustrated in FIG. 7, during the weak erasure operation, the flash memory 201 applies a selection voltage (for example, 0 V) to all the word lines WL in the selected block. The flash memory 201 applies the voltages VSGD and VSGS to the drain side and source side select gate lines SGD and SGS, respectively. Consequently, in each of the string units SU, the select transistors ST1 and ST2 are turned on.

The flash memory 201 applies a voltage V_{WE} to the semiconductor pillar 31 via the well region 20. Here, the voltage V_{WE} applied to the semiconductor pillar 31 is a weak erasure voltage.

A voltage value (the potential CPWELL of the well region 20) of the weak erasure voltage V_{WE} is controlled so as to increase stepwise until reaching the maximum voltage value V3. For example, the maximum voltage value V3 of the weak erasure voltage V_{WE} is smaller than the maximum voltage value V4 of an erasure voltage V_{ER1} for setting a block to be in an erased state.

Consequently, as shown in FIG. 8B which is a schematic diagram illustrating the weak erasure operation, among the memory cells MT in the selected block (the invalid data block), a threshold voltage of the memory cell MT having a threshold voltage which is higher than the neutral threshold voltage Vnu shifts to a value (for example, about 0 V) around the neutral threshold voltage Vnu.

The application of the weak erasure voltage V_{WE} may be performed twice or more in a consecutive or non-consecutive manner in one conservation mode setting sequence. When the application of the weak erasure voltage V_{WE} is performed multiple times, a voltage value of the weak erasure voltage V_{WE} may differ for each timing of the application of the weak erasure voltage V_{WE}. During the weak erasure operation, a voltage higher than 0 V may be applied to the word line WL.

The weak erasure operation for setting the conservation mode is different from a normal erasure operation for setting the memory cell MT to be in an erased state only in terms of the magnitude a voltage applied to the well region, and most of control for performing the weak erasure operation is substantially the same as the erasure operation for setting a block to be in an erased state.

In the sequence of setting a conservation mode block, the weak program operation may be performed after the weak erasure operation is performed. In order to set a memory cell to be in a more electrically neutral state, verification may be performed during the weak erasure operation and exhaust weak program operation.

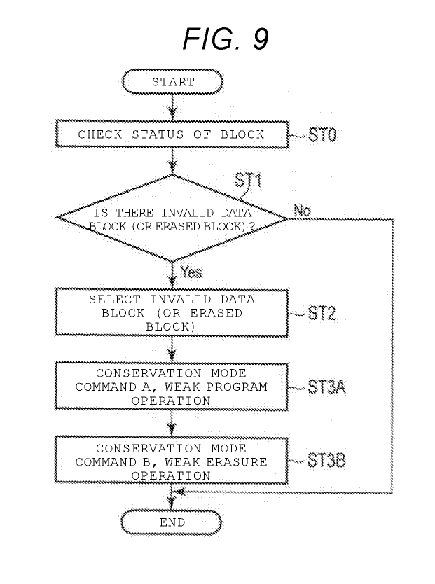

In the operation example (control method) illustrated in FIG. 6, the flash memory 201 continuously performs the weak program operation and the weak erasure operation by using a single command. However, as illustrated in FIG. 9 (a flowchart illustrating an operation example of the memory system), the conservation mode command may be divided into a command for the weak program operation and a command for the weak erasure operation. In this case, the flash memory 201 performs the weak program operation with using one command and performs the weak erasure operation with using the other command.

In the operation example illustrated in FIG. 9, when the memory controller 200 detects that all the memory cells MT in the block are in an erased state in determination of a status (an valid data block or an invalid data block) of the block BK, in a sequence of setting a conservation mode for the block BK, the weak program operation is performed without performing the weak erasure operation.

In the present embodiment, by setting a block to be in the conservation mode, a state in which a threshold voltage of the memory cell MT is excessively higher or excessively lower than the neutral threshold voltage Vnu is preferably removed. For this reason, a threshold voltage of the memory cell MT in the conservation mode block BKZ may not be accurately controlled, and a threshold value distribution of the memory cell in the conservation mode block BKZ may be non-uniform as in the threshold value distribution SNx of the memory cell in the conservation mode block BKZ as illustrated in FIG. 5. Therefore, verification for determining a threshold voltage of the memory cell MT of the conservation mode block BKZ may not be performed after the weak program operation and the weak erasure operation are performed. Consequently, the memory system in this operation example may prevent a period of a sequence of setting a conservation mode block from being lengthened.

A threshold value of the memory cell MT in a selected block belongs to a threshold value distribution of the conservation mode through the weak program operation and the weak erasure operation. Consequently, the block BKZ in the flash memory 201 is set to be in the conservation mode.

For example, the controller 200 records an address of the conservation mode block BKZ in the management table TBL of the flash memory 201. The flag FLG indicating that the block BK is a conservation mode block may be recorded in the flash memory 201.

As mentioned above, in the present embodiment, a block which does not store valid data waits (or is preserved) in a state of being set as the conservation mode block BKZ.

The voltage value V1 of the weak program voltage V_{WP} and the voltage value V3 of the weak erasure voltage V_{WE} are set as appropriate based on characteristics of the flash memory (for example, the number of bits of data stored in the memory cell), a neutral threshold voltage of the memory cell MT (a material of the charge storage layer), a result of a test made for the flash memory 201, an order of the weak program operation and the weak erasure operation, and the like.

As described above, in the memory system according to the present embodiment, a status of a block in the flash memory is set to be in the conservation mode.

<Writing of Data to Conservation Mode Block>

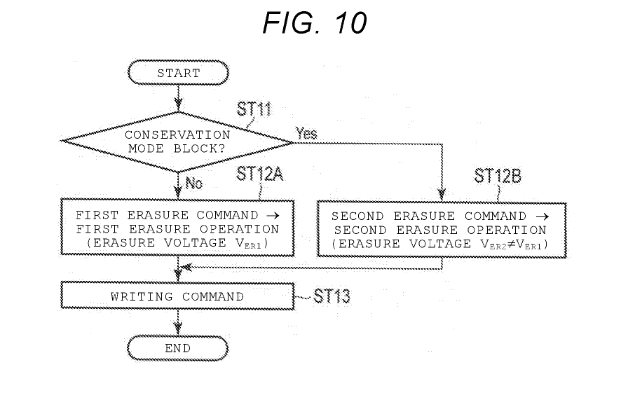

When there is a request for writing data from the host device, the memory controller 200 and the flash memory 201 write data to the memory cell array including a conservation mode block according to a process in a flowchart showing an operation example (a control method for the flash memory) as illustrated in FIG. 10.

The memory controller 200 starts a sequence (writing sequence) for writing data in response to a request from the host device 9.

In the writing sequence, the memory controller 200 determines whether or not a selected block BK including a region (a page, a cluster, a sector, or the like) to which data will be written is the conservation mode block BKZ before writing the data to the selected block (a writing target block) (before applying a program voltage) (step ST11).

For example, the memory controller 200 determines the conservation mode block BKZ based on a result of referring to the management table TBL. The conservation mode block BKZ may be determined through a determination (reading of data) using a determination level of a threshold value state of the memory cell, or by the flag FLG in the flash memory 201.

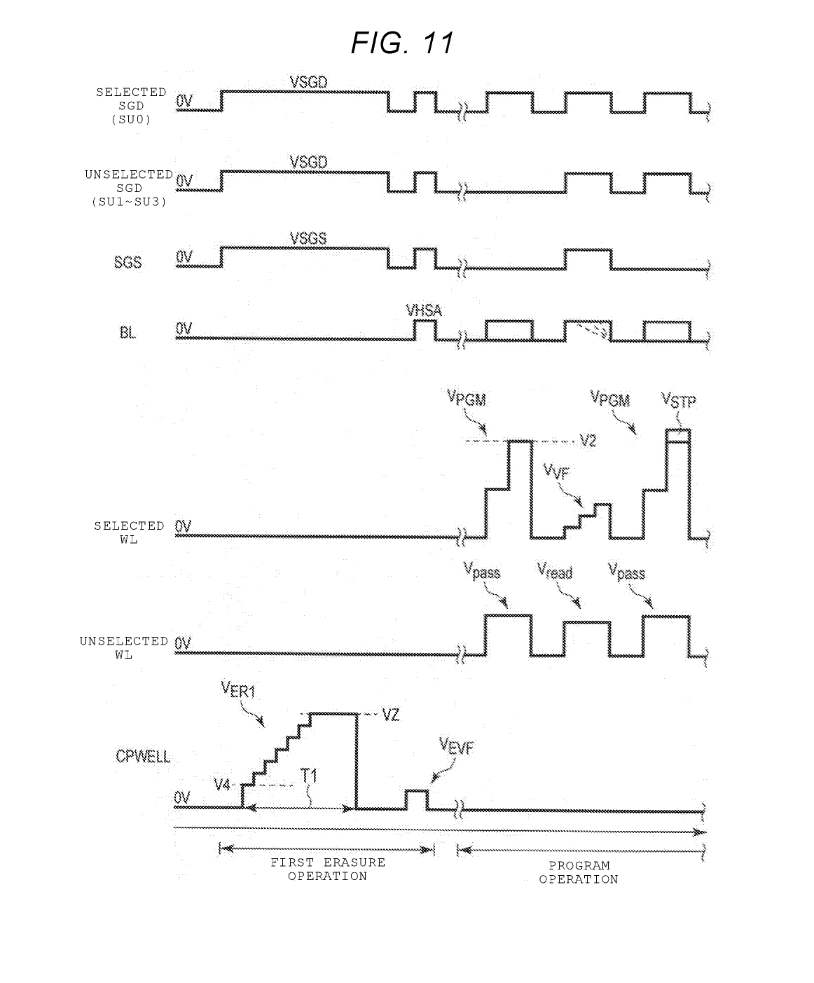

When a selected block is not a conservation mode block (for example, when the selected block is a valid data block), the flash memory 201 performs a first erasure operation using a first erasure voltage V_{ER1} on the selected block as shown in a flowchart of FIG. 11 (illustrating changes in potentials of respective lines of the flash memory) (step ST12A).

The first erasure voltage V_{ER1} has a pulse waveform (a final voltage value VZ and a pulse width T2) which shifts a threshold voltage of the memory cell MT in the highest program state (herein, the C state SC) to a voltage value corresponding to an erased state. A voltage value of the erasure voltage V_{ER1} is set to be gradually heightened by adding a step-up voltage of a certain value to an initial voltage value V4.

For example, the flash memory 201 performs erasure verification on the block which underwent the erasure operation. In this case, the flash memory 201 (the sequencer 16) applies a voltage of 0 V to the word line WL, and applies an erasure verification voltage V_{EVF} to the well region CPWELL. For example, a certain voltage VHSA is applied to the bit line BL.

The erasure verification may be performed not by applying the verification voltage to the well region but by applying the erasure verification voltage V_{EVF} of about 0.5V to the word line WL.

When a result of the erasure verification is a failure, an erasure voltage V_{ER1} to which a step voltage of a certain magnitude is added is applied to the well region 20. The application of the erasure voltage V_{ER1} and the erasure verification are repeatedly performed until the erasure verification passes.

It should be noted that valid data in the selected block may be transmitted to a memory region (for example, a RAM) of the memory controller before the erasure operation is performed.

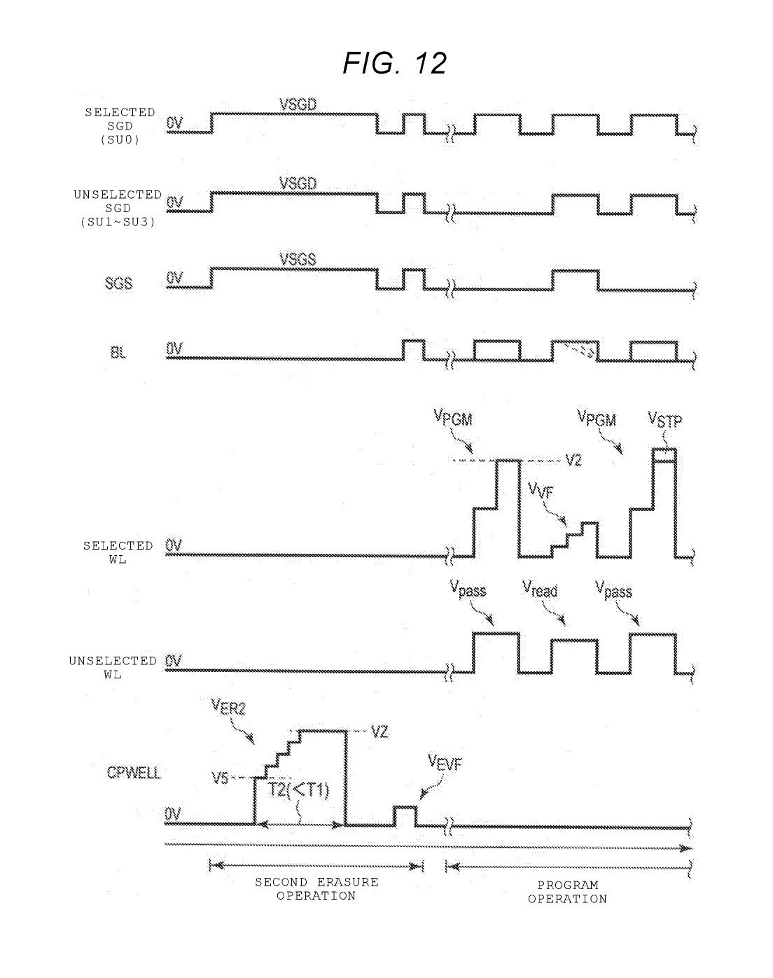

When the selected block is a conservation mode block BKZ, as shown in a timing diagram of FIG. 12, the flash memory 201 performs a second erasure operation using a second erasure voltage V_{ER2} on the selected block (step ST12B).

In the erasure operation on the conservation mode block BKZ, the erasure voltage V_{ER2} has a pulse waveform which is different from the pulse waveform of the erasure voltage V_{ER1}.

An amount of change in a threshold voltage of the memory cell MT from a neutral state to an erased state is smaller than an amount of change in a threshold voltage of the memory cell MT from a program state to the erased state. For this reason, in the erasure voltage V_{ER2}, a voltage difference between an initial voltage value V5 and a final voltage value VZ is reduced. Consequently, the number of times of adding a step voltage is reduced. As a result, a pulse width (a period of applying an erasure voltage) T2 of the erasure voltage V_{ER2} may be made shorter than the pulse width T1 of the erasure voltage V_{ER1}. Therefore, a period for shifting a threshold value state of the memory cell MT from the neutral state to the erased state is shorter than a period for shifting the threshold value state of the memory cell MT from the program state to the erased state.

Consequently, the period T2 of the erasure operation on the conservation mode block BKZ is shorter than the period T1 of the erasure operation on a block (for example, a valid data block) which stores data.

As a result, in this operation example of the memory system provided with the flash memory 201 including the conservation mode block BKZ, a period from an erasure operation to writing (a program operation) of data, occupying a period of using the memory system, may be reduced. For example, in a memory system (storage device) in which the frequency of rewriting of data is high, as in the present embodiment, reducing a period of the erasure operation which is performed before data is written is effective.

In the present embodiment, in the erasure operation from the neutral state to the erased state, a period in which an electron passes through the gate insulating film is shorter than in the erasure operation from the program state to the erased state. In the memory system of the present embodiment, deterioration of the gate insulating film of the memory cell MT caused by the passage of the electron may be minimized.

For example, the flash memory 201 performs erasure verification on the conservation mode block BKZ which has been subjected to the second erasure operation in the same manner as in the first erasure operation.

When a result of the erasure verification is a failure, an erasure voltage V_{ER2} to which a step voltage of a certain magnitude is added is applied to the well region. The application of the erasure voltage and the erasure verification are repeatedly performed until the erasure verification passes.

When a result of the erasure verification is successful in the erasure operation on the valid data block or the conservation mode block, the flash memory 201 notifies the memory controller 200 of completion of the erasure on the block.

Based on this notification, the memory controller 200 controls various control signals, and transmits a write command, an address, and data to be written to the flash memory 201 via the I/O line (step ST13).

The flash memory 201 (the sequencer 16) starts a process for applying a program voltage V_{PRG}.

As illustrated in FIGS. 11 and 12, the flash memory 201 performs one or more program operations (writing loop) including application of the program voltage V_{PRG} and program verification as a writing sequence corresponding to a command. Consequently, the flash memory 201 writes data in a selected address.

For example, in the present embodiment, the application of the program voltage V_{PRG} and the program verification are performed according to a well-known method. As an example of the program operation, the flash memory 201 controls potentials of the select gate lines SGD and SGS and the bit line BL, and then applies the program voltage V_{PRG} of a certain voltage value (initial value) V2 to a selected word line WL. The flash memory 201 applies a non-selection potential Vpass to an unselected word line. The non-selection potential Vpass may be applied to the selected word line WL and then the voltage value V2 may be applied thereto.

During the program operation in the memory cell array having the configuration illustrated in FIGS. 3 and 4, for example, a single string unit (for example, the unit SU0) is selected from the plurality of string units SU. The flash memory 201 applies the voltage VSGD to the drain side select gate line (herein, the select gate line SGD0) in the selected string unit. Thus, the select transistor ST1 in the selected string unit is turned on. A voltage of 0 V is applied to the drain side select gate lines SGD1 to SGD3 of the unselected string units. Thus, the select transistors ST1 in the unselected string units SU1 to SU3 are turned off. A voltage of 0 V is applied to the source side select gate line SGS. As a result, when the program voltage VPGM is applied, the select transistor ST2 is turned off.

The flash memory 201 applies a voltage of a magnitude corresponding to data to be written, to the bit line BL. For example, a voltage of 0 V is applied to the bit line BL connected to a memory cell to which the data will be written. A voltage (the voltage VHSA higher than 0 V) of a certain magnitude is applied to the bit line BL connected to a memory cell to which writing of data is not necessary.

Electric charge is injected into the charge storage layer of the memory cell according to the magnitude of the program voltage V_{PGM} and the potential of the bit line BL. Consequently, a threshold voltage of the memory cell MT shifts to a positive direction.

As mentioned above, during writing of data, the voltage VSGD for turning on the select transistor ST1 is applied to the drain side select gate line SGD in the selected single string unit, and the turning-on voltage VSGD is not applied to the drain side select gate lines SGD in the unselected string units.

Next, in order to determine a threshold value state of the memory cell MT, the flash memory 201 charges the bit line BL, and applies a verification voltage V_{VF} to a selected word line. The flash memory 201 applies a non-selection voltage V_{READ} to an unselected word line. The verification voltage V_{VF} includes a plurality of voltage values (determination levels) corresponding to program states (data to be stored).

When the memory cell MT is turned on by the verification voltage V_{VF}, the bit line BL is discharged. In contrast, when the memory cell MT is turned off during the application of the verification voltage V_{VF}, the charging state of the bit line BL is maintained. By detecting charging and discharging of the bit line BL, it can be determined whether or not a threshold voltage of the memory cell has shifted to a value corresponding to data to be stored.

When the program verification fails, the flash memory 201 performs the above-described program operation on valid data with using the program voltage V_{PGM} to which a step voltage V_{STP} is added.

When the program verification is successful, the flash memory 201 notifies the memory controller 200 of completion of writing of the data.

The memory controller 200 and the flash memory 201 records information indicating a status of the block based on the data writing result, in the management table TBL.

Reading of data from a block or a page which is converted from the conservation mode block BKZ to a valid data block is performed according to a well-known reading method.

As mentioned above, in the memory system according to the present embodiment, writing of data to the flash memory including the conservation mode block is completed.

In the operations of the memory system illustrated in FIGS. 6 to 12, the write command may include control signals (flags) indicating processes for determining a conservation mode of a block and for selecting an erasure operation corresponding to a status of the block.

### (c) Conclusion

The memory system according to the present embodiment sets a block (for example, an invalid data block) which does not store valid data to be in a conservation mode as one of the states of the block of the flash memory 201. In the block set to be in the conservation mode, a threshold value distribution of a plurality of memory cells MT is set to be in substantially an electrically neutral state (for example, a state in which an influence of charging of the charge storage layer may be disregarded). Consequently, the charge storage layer of the memory cell MT is electrically stabilized.

Therefore, a potential difference between the charge storage layer and the semiconductor substrate (semiconductor pillar) is reduced. As a result, according to the present embodiment, deterioration in the gate insulating film caused by application of the potential difference is minimized.

The present embodiment may prevent electric charge from being captured by neutral defects in the gate insulating film and may thus reduce the number of electrons captured in the gate insulating film. Consequently, the release of electric charge from the neutral defects does not occur much in a program state of the memory cell. Therefore, according to the present embodiment, a variation in a threshold voltage of the memory cell after data is written is minimized.

Thus, the memory system according to the present embodiment may minimize deterioration in the memory retention characteristic.

### (2) Second Embodiment

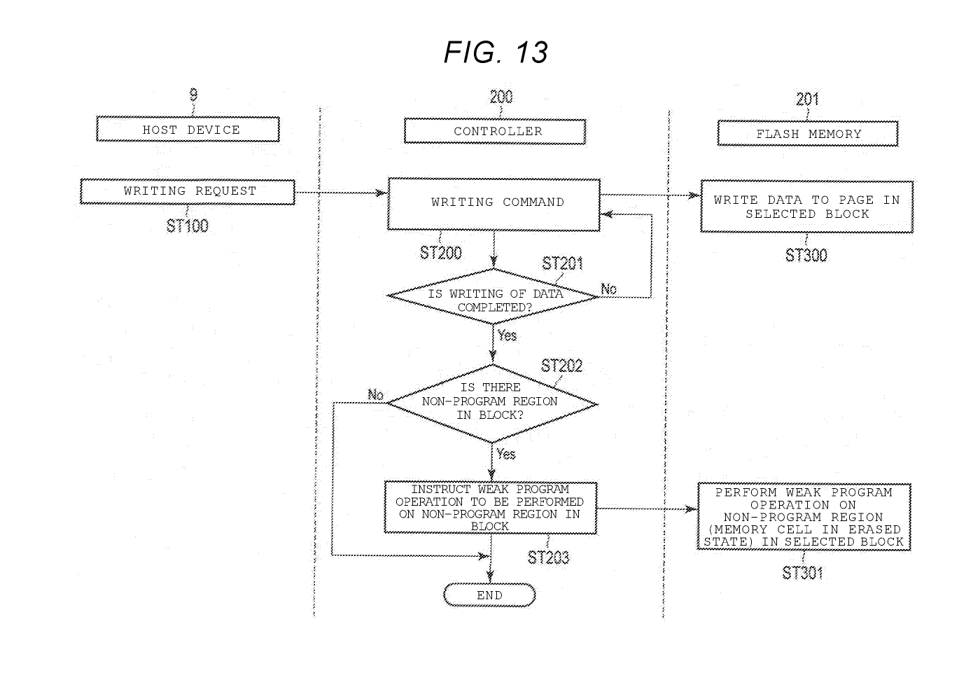

With reference to FIG. 13, a memory system according to a second embodiment will be described. Herein, the second embodiment will be described by appropriately referring to FIGS. 1 to 12.

There is a case where a region (hereinafter, referred to as a non-program region) including a memory cell which is not selected as a data writing target is present in a valid data block depending on a size of data to be stored. The memory cell in the non-program region (also referred to as an unused region or an erased region) is in an erased state. A plurality of memory cells may be in an erased state for a long period of time.

As a result, there is a possibility that the retention characteristic of the memory cell may deteriorate due to a potential difference (stress) applied to the gate insulating film, or capturing or release of electric charge in neutral defects.

The memory system (and the storage device and the flash memory) according to the present embodiment sets a threshold value distribution of a plurality of memory cells of the non-program region to be in a neutral state as follows. In other words, some memory cells in a valid data block are set to be in a conservation mode state.

FIG. 13 is a flowchart illustrating an operation example (control method) of the memory system. The host device 9 transmits a write request and data to be written to the memory controller 200 (step ST100).

The memory controller 200 transmits a write command and the data to be written to the flash memory 201 based on the write request (step ST200). For example, the data to be written is divided into data items in the unit data sizes, and the divided data items are sequentially transmitted to the flash memory 201 from the memory controller 200.

The flash memory 201 performs an erasure operation on a selected block, and then sequentially writes the data to be written, into the selected block in the page unit. In the present embodiment, the erasure operation is performed according to steps ST11, ST12A and ST12B of FIG. 10, and the operations illustrated in FIGS. 11 and 12.

For example, the memory controller 200 may monitor the progress of the writing sequence in the flash memory 201.

The memory controller 200 determines whether or not programming of all data to be written is completed, for example, by checking a state of the ready/busy signal (step ST201).

When all the data to be written are not completed, the memory controller 200 transmits remaining data to be written to the flash memory 201 along with a write command and causes the flash memory 201 to write the data.

The memory controller 200 repeatedly performs the instruction (step ST200) for writing data and the determination (step ST201) of completion of writing until all data to be written is written into the flash memory 201.

When the memory controller 200 detects completion of writing of the data, the memory controller 200 determines whether or not there is a non-program region in the selected block (step ST202). For example, when a plurality of blocks are selected, the memory controller 200 determines the presence or absence of a non-program region for each block.

The determination of the non-program region in the selected block may be performed based on detection of an unselected word line (unselected address), determination of a threshold voltage of a memory cell using a certain determination level, comparison between a size of data to be written and a storage capacity of the block, and the like.

When a non-program region is not detected in the selected block, that is, when all regions (pages) in the block BK are in a program state (a valid data retention state), the memory controller 200 finishes the writing sequence on the flash memory 201. The memory controller 200 notifies the host device 9 of completion of writing of data.

When a non-program region is detected in the selected block, the memory controller 200 transmits a command CMDZ and an address of the non-program region to the flash memory 201. The command CMDZ is a command (hereinafter, also referred to as a weak program command) for instructing the weak program operation to be performed on a memory cell of the non-program region in the valid data block.

The command register 199 holds the command CMDZ. The sequencer 16 analyzes the supplied command as the weak program command CMDZ. The flash memory 201 performs the weak program operation on the memory cell MT (the memory cell in an erased state) of the non-program region indicated by the address based on the weak program command CMDZ. A threshold value distribution of a plurality of memory cells MT in the non-program region shifts from the erased state to a neutral state (for example, about 0 V) due to the weak program operation.

Consequently, the non-program region in the valid data block is set to be in a conservation mode.

For example, the memory controller 200 records the fact that the non-program region (hereinafter, also referred to as a conservation mode page) set to be in the conservation mode is present in the valid data block, in the management table TBL. The flash memory 201 may record a flag indicating the presence of the conservation mode page in the flash memory 201.

As mentioned above, in the memory system according to the present embodiment, writing of data to the valid data block of the flash memory and setting of the conservation mode for the non-program region are completed.

After data is written, some regions in a valid data block may become regions (hereinafter, also referred to as invalid data regions) which do not store valid data depending on a use situation of the flash memory. The memory system according to the present embodiment may set the invalid data region in the valid data block to be in a neutral state as follows. For example, the memory controller 200 detects an invalid data region (for example, a page retaining invalid data) in the valid data block based on the management table TBL. The memory controller 200 sets a memory cell of the invalid data region to be in the neutral state by performing at least one of the weak erasure operation and the weak program operation on the detected invalid data region. Consequently, the memory system according to the present embodiment may reduce a potential difference for the gate insulating film of the memory cell in the invalid data region.

In the present embodiment, a memory cell in an erased state at a certain portion of a page may be set to be in a neutral state.

As described above, the flash memory according to the present embodiment may prevent a threshold value distribution of a plurality of memory cells of the non-program region from being in an erased state for a long period of time.

As a result, according to the present embodiment, a variation in a threshold voltage of the memory cell MT due to capturing and release of electric charge in neutral defects may be minimized.

Therefore, the memory system according to the second embodiment may minimize deterioration in the retention characteristic of the memory cell of the flash memory.

In the operation examples of the memory system illustrated in FIGS. 6 and 7, when an invalid data block is set to be in the conservation mode, verification may be performed on a block to be set to be in the conservation mode after the weak program operation and the weak erasure operation are performed. The verification operation in the conservation mode is performed with using an upper limit value and a lower limit value (for example, an upper limit value and a lower limit value of allowable values which ensure a neutral state of a memory cell) of voltage values corresponding to a neutral state.

In the first erasure operation of the flash memory 201 illustrated in FIGS. 10 and 11, the maximum voltage value V4 of a voltage which is initially applied to the well region which is formed in the upper portion of the semiconductor substrate and over which the memory cells are arranged is a value in a range, for example, from 12 V to 13.6 V. The voltage value V4 is not limited to this value, and may be a value in any one of ranges, for example, from 13.6 V to 14.8 V, from 14.8 V to 19.0 V, from 19.0 V to 19.8 V, and from 19.8 V to 21 V.

The period T1 of the first erasure operation may be any one of periods within ranges, for example, from 3,000 μs to 4,000 μs, from 4,000 μs to 5,000 μs, and from 4,000 μs to 9,000 μs. However, the period T1 of the first erasure operation may be 1 ms to 5 ms depending on characteristics (types) of flash memories.

A reading operation on a multi-value flash memory includes the following determination voltage.

A determination voltage applied to a word line which is selected in a reading operation in the A level is within a range, for example, from 0 V to 0.55 V. However, the A level determination voltage is not limited to this value, and may be within any one of ranges, for example, from 0.1 V to 0.24 V, from 0.21 V to 0.31 V, from 0.31 V to 0.4 V, from 0.4 V to 0.5 V, and from 0.5 V to 0.55 V.

A determination voltage applied to a word line which is selected in a reading operation in the B level is within a range, for example, from 1.5 V to 2.3 V. However, the B level determination voltage is not limited to this value, and may be within any one of ranges, for example, from 1.65 V to 1.8 V, from 1.8 V to 1.95 V, from 1.95 V to 2.1 V, and 2.1 V to 2.3 V.

A determination voltage applied to a word line which is selected in a reading operation in the C level is within a range, for example, from 3.0 V to 4.0 V. However, the C level determination voltage is not limited to this value, and may be within any one of ranges, for example, from 3.0 V to 3.2 V, from 3.2 V to 3.4 V, from 3.4 V to 3.5 V, from 3.5 V to 3.6 V, and from 3.6 V to 4.0 V.

The period (tR) of the reading operation may be any one of periods within ranges, for example, from 25 μs to 38 μs, from 38 μs to 70 μs, and from 70 μs to 80 μs.

A writing operation on the multi-value flash memory includes a program operation and a verification operation.

In the writing operation on the multi-value flash memory, a voltage which is initially applied to a word line selected during the program operation is within a range, for example, 13.7 V to 14.3 V. The voltage is not limited to this value, and may be within any one of ranges, for example, 13.7 V to 14.0 V, and from 14.0 V to 14.6 V.

A voltage which is initially applied to a selected word line during a writing operation on memory cells of odd-numbered word lines may be different from a voltage which is initially applied to a selected word line during a writing operation on memory cells of even-numbered word lines.

When the program operation is of an incremental step pulse program (ISPP) type, a step-up voltage is, for example, about 0.5 V.

A non-selection voltage (pass voltage) applied to an unselected word line has a value in a range of, for example, from 6.0 V to 7.3 V. However, the non-selection voltage is not limited to this value, and may be a value in a range, for example, from 7.3 V to 8.4 V, and may be a value of 6.0 V or lower.

An applied pass voltage may be changed depending on whether an unselected word line is an odd-numbered word line or an even-numbered word line.

The period (tProg) of the writing operation may be any one of periods within ranges, for example, from 1,700 μs to 1,800 μs, from 1,800 μs to 1,900 μs, and from 1,900 μs to 2,000 μs.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a semiconductor memory device that includes a plurality of memory cells; and
a controller that controls an operation of the semiconductor memory device to set the memory cells to have a threshold voltage distribution corresponding to data being written therein, when data is being written in the memory cells, and to set the memory cells to have a neutral threshold voltage distribution, the neutral threshold voltage distribution being different from any of a plurality of threshold voltage distributions corresponding to valid data, when data is not being written in the memory cells.

2. The memory system according to claim 1, wherein the neutral threshold voltage distribution is substantially centered at a neutral threshold voltage.

3. The memory system according to claim 2, wherein the neutral threshold voltage is 0.

4. The memory system according to claim 2, wherein the neutral threshold voltage is between centers of two adjacent valid data threshold distributions.

5. The memory system according to claim 1, wherein the neutral threshold voltage distribution overlaps parts of two valid data threshold distributions.

6. The memory system according to claim 1, wherein the controller performs a normal erase operation using a first erase voltage when performing an erase operation of the memory cells and a weak erase operation using a second erase voltage, lower than the first erase voltage, in a process of setting the memory cells to have the neutral threshold voltage distribution.

7. The memory system according to claim 6, wherein the process of setting the memory cells to have the neutral threshold voltage distribution further includes increasing threshold voltages of some of the memory cells.

8. The memory system according to claim 1, wherein the controller performs a normal programming operation using a first programming voltage when performing a write operation on the memory cells and a weak programming operation using a second programming voltage, lower than the first programming voltage, in a process of setting the memory cells to have the neutral threshold voltage distribution.

9. A memory system comprising:
a semiconductor memory device that includes a plurality of blocks of memory cells, wherein each of the blocks is an erasure unit; and
a controller that controls an operation of the semiconductor memory device, wherein
during a write operation performed on a first group of memory cells of a block, the controller performs a first programming operation on the first group of memory cells so that the memory cells in the first group are set to have a threshold voltage distribution corresponding to data being written therein, and performs a second programming operation on a second group of memory cells of the block so that the memory cells in the second group are set to have a neutral threshold voltage distribution, the neutral threshold voltage distribution being different from any of a plurality of threshold voltage distributions corresponding to valid data.

10. The memory system according to claim 9, wherein the neutral threshold voltage distribution is substantially centered at a neutral threshold voltage.

11. The memory system according to claim 10, wherein the neutral threshold voltage is 0.

12. The memory system according to claim 10, wherein the neutral threshold voltage is between centers of two adjacent valid data threshold distributions.

13. The memory system according to claim 9, wherein the neutral threshold voltage distribution overlaps parts of two valid data threshold distributions.

14. A method of preserving data retention characteristics of memory cells in a semiconductor memory device, comprising:
checking a status of a block of memory cells;
determining that the block is an invalid data block or an erased block; and
setting the memory cells of the block to have a neutral threshold voltage distribution, the neutral threshold voltage distribution being different from any of a plurality of threshold voltage distributions corresponding to valid data.

15. The method according to claim 14, wherein the neutral threshold voltage distribution is substantially centered at a neutral threshold voltage.

16. The method according to claim 15, wherein the neutral threshold voltage is 0.

17. The method according to claim 15, wherein the neutral threshold voltage is between centers of two adjacent valid data threshold distributions.

18. The method according to claim 14, wherein the neutral threshold voltage distribution overlaps parts of two valid data threshold distributions.

19. The method according to claim 14, wherein
if the block is an invalid block, setting the memory cells of the block to have a neutral threshold voltage distribution by performing a weak erase operation on the memory cells using an erase voltage that is lower than an erase voltage used in a normal erase operation.

20. The method according to claim 14, wherein
if the block is an erased block, setting the memory cells of the block to have a neutral threshold voltage distribution by performing a weak programming operation on the memory cells using a programming voltage that is lower than a programming voltage used in a normal programming operation.
